(19) United States
(12) Patent Application Publication
(10) Pub. No.: US 2026/0267260 A1
(43) Pub. Date: Sep. 10, 2026

(54) IMAGE FORMING APPARATUS

(71) Applicant: CANON KABUSHIKI KAISHA, Tokyo (JP)

(72) Inventors: Satoshi Koga, Shizuoka (JP); Kazuhiko Aono, Shizuoka (JP); Masatoshi Itoh, Shizuoka (JP); Yuya Kino, Shizuoka (JP)

(21) Appl. No.: 19/553,622

(22) Filed: Mar. 2, 2026

(30) Foreign Application Priority Data
Mar. 6, 2025 (JP) 2025-035940

(51) Int. Cl. G03G 15/08; G01R 19/00; G03G 15/00; G03G 21/16; G03G 21/18

(52) U.S. Cl. CPC G03G 15/0856; G01R 19/0092; G03G 15/0808; G03G 15/556; G03G 15/80; G03G 21/1619; G03G 21/1814; G03G 21/1867

(57) ABSTRACT

An image forming apparatus includes a developing unit has first and second electrode portions provided so as to face each other with a space therebetween inside of an accommodating portion that accommodates developer, and first and second electrical contact portions that are electrically connected to the first and second electrode portions, respectively, and are exposed to an outside of the developing unit. An apparatus main body has a power source that applies voltage between the first electrical contact portion and the second electrical contact portion, and a current detection portion that detects a current flowing between the first electrode portion and the second electrode portion, and the current detection portion is provided between one end and another end of a photosensitive drum in a rotation axis direction of the photosensitive drum, and is provided between an exposure unit and the developing unit when viewed in the rotation axis direction.

### BACKGROUND

### Field of the Technology

The present disclosure relates to a means for detecting a remaining amount of toner in a process cartridge and a toner cartridge that are attached to and detached from an image forming apparatus using an electrophotographic method.

### Description of the Related Art

An electrostatic capacitance method has been conventionally known as a toner remaining amount detection means for detecting a remaining amount of toner (developer) in a toner accommodating portion of a process cartridge and a toner cartridge. In Japanese Patent Application Laid-Open No. 2013-029543, an alternating current voltage is applied to one of two electrode members provided in the toner accommodating portion, and the amount of toner in the toner accommodating portion is detected using an alternating current detected by the other electrode member.

When a configuration such as that of Japanese Patent Application Laid-Open No. 2013-029543 is used, it is necessary to arrange a substrate on which a current detection circuit is mounted on the image forming apparatus main body side. The substrate and the electrode that detects the current in the toner accommodating portion are connected by a signal line. When the electrostatic capacitance between the electrodes in the toner accommodating portion is minute, the signal line is greatly affected by stray capacitance generated between the signal line and the frame ground and by stray capacitance between the signal line and other signal lines. Due to this influence, current detection accuracy decreases, and therefore it has been necessary to adopt a configuration in which the signal line secures a distance from the frame ground and other signal lines. Therefore, there is a problem that space for securing the distance is required, and the product size increases.

### SUMMARY

The present disclosure is directed to provide a technology capable of suppressing a decrease in detection accuracy of a remaining amount of developer.

In order to solve the above problem, an image forming apparatus according to the present disclosure includes:

a photosensitive drum that rotates about a rotation axis, the photosensitive drum having a first end that is one end in a direction of the rotation axis and a second end that is another end in the direction of the rotation axis;

a developing unit having a developing roller that supplies developer to the photosensitive drum, and an accommodating portion that accommodates developer to be borne on the developing roller; and

an apparatus main body having an exposure unit that exposes the photosensitive drum,

wherein the developing unit has a first electrode portion and a second electrode portion, and a first electrical contact portion and a second electrical contact portion, the first electrode portion and the second electrode portion being provided so as to face each other with a space therebetween inside of the accommodating portion, the first electrical contact portion being electrically connected to the first electrode portion and exposed to an outside of the developing unit, the second electrical contact portion being electrically connected to the second electrode portion and exposed to the outside of the developing unit,

wherein the apparatus main body has a power source and a current detection portion, the power source being configured to apply an alternating current voltage between the first electrical contact portion and the second electrical contact portion, the current detection portion being configured to detect a current flowing between the first electrode portion and the second electrode portion, and

wherein the current detection portion is provided between the first end and the second end of the photosensitive drum in the direction of the rotation axis, and is provided between the exposure unit and the developing unit when viewed in the direction of the rotation axis.

Features of the present disclosure will become apparent from the following description of embodiments with reference to the attached drawings. The following description of embodiments is described by way of example.

### BRIEF DESCRIPTION OF THE DRAWINGS

FIG. 1 is a cross-sectional view showing a schematic configuration of a monochrome laser printer.

FIG. 2 is a sectional view of a process cartridge.

FIG. 3 is a perspective view of the process cartridge.

FIG. 4A is a perspective view of an electrode holder that holds a first electrode and a second electrode.

FIG. 4B is a perspective view in which the electrode holder is removed from the state shown in FIG. 4A.

FIG. 5A is a perspective view showing a positional relationship between the process cartridge and a laser scanner when viewed from the rear upper side.

FIG. 5B is a perspective view showing a positional relationship between the process cartridge and the laser scanner when viewed from the front upper side.

FIG. 6A is a perspective view of a frame member viewed from below.

FIG. 6B is a perspective view in which a cover member is removed from FIG. 6A.

FIG. 7A is a perspective view of a second substrate, a substrate holder, a first spring, and a second spring.

FIG. 7B is a perspective view of the second substrate, the substrate holder, the first spring, and the second spring when viewed from an angle different from FIG. 7A.

FIG. 7C is a perspective view of the second substrate, the substrate holder, the first spring, and the second spring when viewed from an angle different from FIGS. 7A and 7B.

FIG. 8 is a cross-sectional view showing a relationship among the laser scanner, the second substrate, and the electrical contacts.

FIG. 9 is a cross-sectional view showing a relationship among the laser scanner, the second substrate, and the electrical contacts according to a modification of the present embodiment.

FIG. 10A is a perspective view of the process cartridge and the toner cartridge in a state where the process cartridge and the toner cartridge are integrated.

FIG. 10B is a perspective view of the process cartridge and the toner cartridge in a state where the process cartridge and the toner cartridge are separated.

FIG. 11A is a perspective view of the toner cartridge.

FIG. 11B is a perspective view of the toner cartridge with the cover member removed.

FIG. 12 is a cross-sectional view of the process cartridge and the toner cartridge.

FIG. 13A is a perspective view of an electrode holder that holds the first electrode and the second electrode according to Embodiment 2.

FIG. 13B is a perspective view in which the electrode holder is removed from the state shown in FIG. 13A.

FIG. 14 is a perspective view showing a positional relationship between the toner cartridge and the laser scanner.

FIG. 15A is a perspective view of the frame member viewed from above.

FIG. 15B is a perspective view in which the cover member is removed from FIG. 15A.

FIG. 16 is a cross-sectional view showing a relationship among the laser scanner, the second substrate, and the electrical contacts.

FIG. 17 is a block diagram of a remaining amount detection circuit.

### DESCRIPTION OF THE EMBODIMENTS

Hereinafter, embodiments of the present disclosure will be described in detail on the basis of embodiments with reference to the drawings. In this regard, the dimensions, materials, shapes, relative arrangements, and the like of the components described in the embodiments may be appropriately modified according to the configurations and various conditions of apparatuses to which the present disclosure is applied. That is, the scope of the present disclosure is not intended to be limited to the embodiments described below. While a plurality of features are described in each of the embodiments, all of the plurality of features are not necessarily essential to the present disclosure and the plurality of features may be combined with each other in any way. Moreover, in the accompanying drawings, the same reference numerals are assigned to the same or similar components, and redundant descriptions thereof are omitted.

Here, an electrophotographic image forming apparatus to which the present disclosure is applicable typically includes a developing unit that is attachable to and detachable from an electrophotographic image forming apparatus main body (hereinafter referred to as "apparatus main body"). The developing unit refers to one that has at least one of toner, a toner accommodating portion, a developer bearing member, and a process unit acting on the developer bearing member, and is attachable to and detachable from the apparatus main body. Representative examples of the developing unit include a developing cartridge, a process cartridge, and a toner cartridge. The developing cartridge is formed into a cartridge including a developer bearing member and a process unit acting on the developer bearing member, and is detachably mounted to the apparatus main body. The process cartridge is formed into a cartridge including an image bearing member and a process unit acting on the image bearing member, and is detachably mounted to the apparatus main body. The toner cartridge accommodates developer (hereinafter referred to as "toner") to be supplied to a developing member such as a developer bearing member, and is detachably mounted to the apparatus main body. In addition, an electrophotographic image forming apparatus is one that forms an image on a recording medium using an electrophotographic image forming method. Examples of the electrophotographic image forming apparatus include, for example, an electrophotographic copying machine, an electrophotographic printer (such as an LED printer or a laser beam printer), a facsimile apparatus, a word processor, and the like.

### Embodiment 1

### Overall Overview of Image Forming Apparatus Main Body

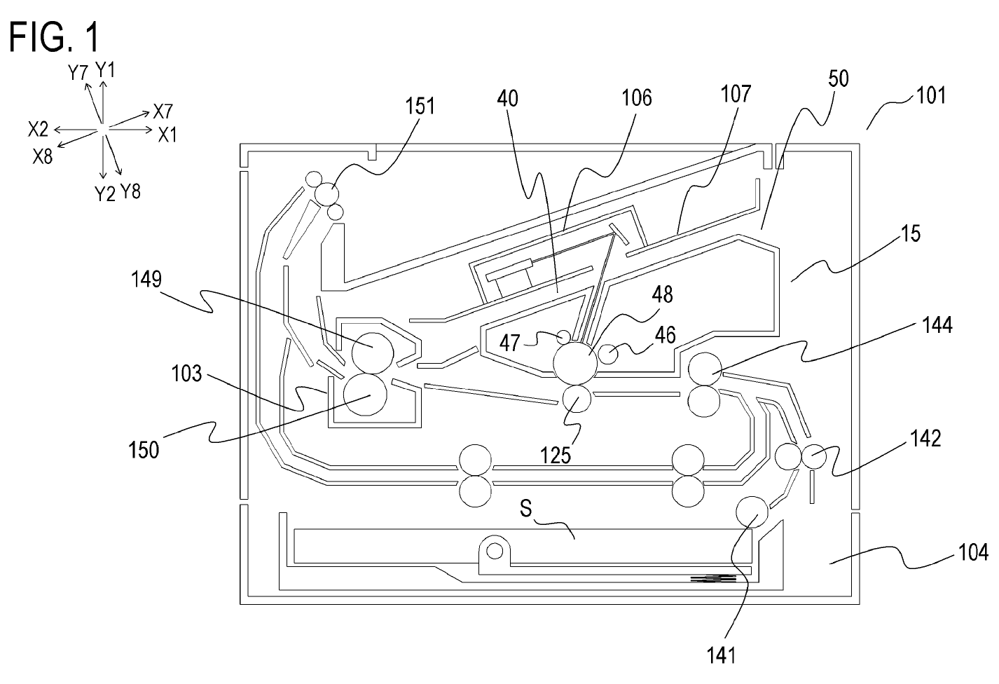

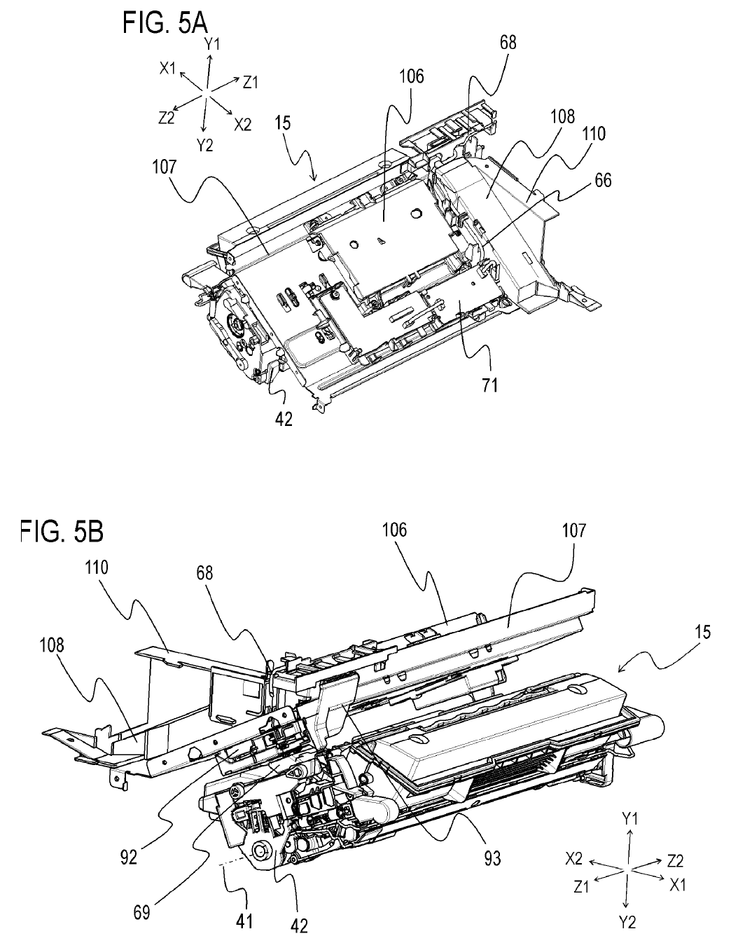

FIG. 1 is a cross-sectional view showing a schematic configuration of a monochrome laser printer as an example of an image forming apparatus. The image forming apparatus main body (hereinafter, apparatus main body 101) shown in FIG. 1 broadly includes a sheet feeding portion, an image forming portion that forms an image on a sheet, a fixing portion, a discharge/reversing portion, and a double-sided conveyance portion. Here, the horizontal direction in the image forming posture of the apparatus main body 101 is defined as X1, X2, and the vertical direction is defined as Y1, Y2. Further, as shown in FIGS. 5A and 5B, a direction perpendicular to both the horizontal direction X1, X2 and the vertical direction Y1, Y2 is defined as a longitudinal direction Z1, Z2. Here, a mounting direction of the process cartridge 15 with respect to the apparatus main body 101 is X7, X8, and a mounting vertical direction is Y7, Y8.

The apparatus main body 101 includes a process cartridge 15 that is attachable to and detachable from the apparatus main body 101. The process cartridge 15 is a process unit for forming a toner image on a sheet S using an electrophotographic process, and has a process member such as a photosensitive drum 48 as an image bearing member, a charging roller 47, and a developing roller 46 as a developer bearing member.

A laser scanner 106 as an exposure unit is arranged above the process cartridge 15, and performs exposure to the photosensitive drum 48 based on an image signal. The photosensitive drum 48 is charged to a predetermined negative polarity potential by the charging roller 47. Thereafter, the laser scanner 106 scans the photosensitive drum 48 with laser light, thereby forming an electrostatic latent image on the photosensitive drum 48. Thereafter, toner is supplied and developed from the developing roller 46 onto the photosensitive drum 48 and visualized as a toner image.

The sheet feeding portion has a sheet feed roller 141 mounted to the apparatus main body 101 and a sheet feed cassette 104 that is attachable to and detachable from the apparatus main body 101. Sheets S accommodated in the sheet feed cassette 104 are separated and fed one by one by the sheet feed roller 141. The fed sheet S is conveyed to a registration roller pair 144 by a conveyance roller pair 142, and skew correction is performed by the registration roller pair 144, and the sheet S is conveyed to a transfer portion.

The transfer portion is configured such that a positive polarity bias is applied to the transfer roller 125 by a bias applying unit (not shown). As a result, the toner image on the photosensitive drum 48 is transferred to the sheet S conveyed to the transfer portion.

The sheet S to which the toner image has been transferred is conveyed to a fixing device 103 provided downstream in a conveyance direction as viewed from the transfer portion. The fixing device 103 fixes the toner image transferred to the sheet S to the sheet, and has a heating unit 149 including a heater as a heating member (not shown) and a pressure roller 150 as a pressure member that rotates in pressure contact with the heating unit 149. The sheet S on which the toner image has been formed is nipped and conveyed in a nip portion formed by the heating unit 149 and the pressure roller 150, and the toner image is fixed to the surface of the sheet S by applying heat and pressure.

The sheet S to which the toner image has been fixed is discharged to the outside of the apparatus by a discharge roller pair 151.

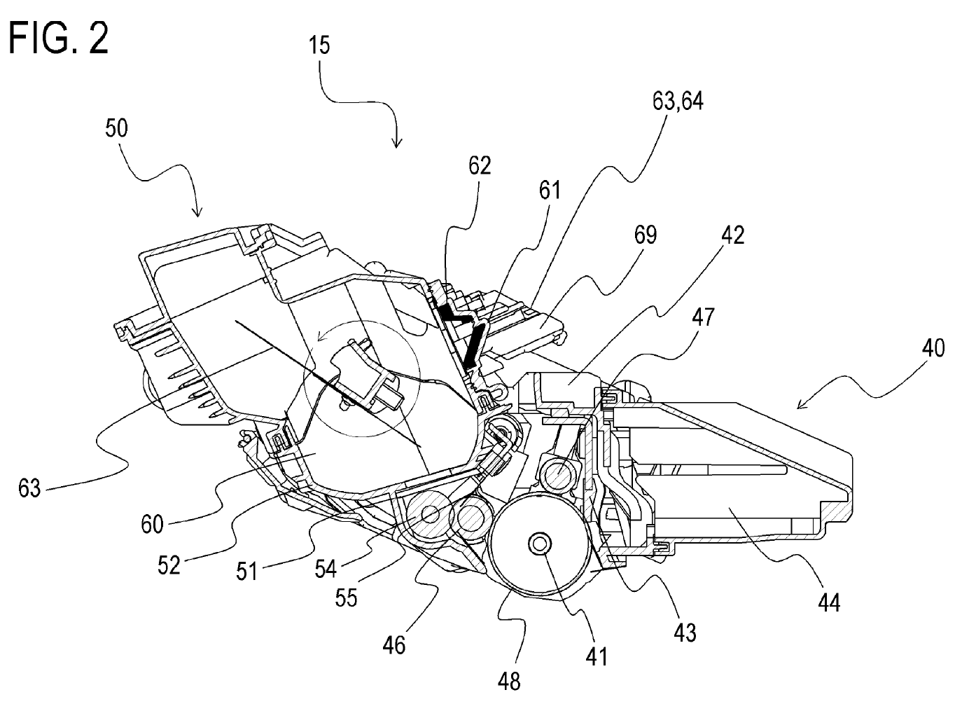

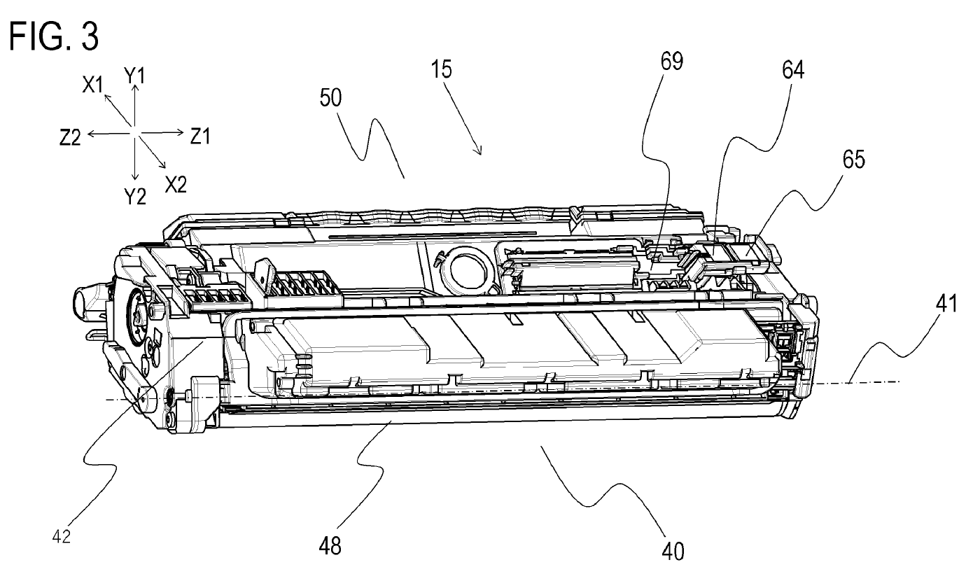

FIG. 2 is a cross-sectional view of the process cartridge 15, and FIG. 3 is a perspective view of the process cartridge 15. The process cartridge 15 includes a cleaning unit 40 including the photosensitive drum 48 and a developing unit 50 including the developing roller 46. The cleaning unit 40 and the developing unit 50 are integrally configured as the process cartridge 15, and are attachable to and detachable from the apparatus main body 101.

The cleaning unit 40 has the photosensitive drum 48, a drum support member 42 that rotatably supports the photosensitive drum 48 around a rotation shaft 41, a cleaning blade 43, and a waste toner accommodating portion 44. The photosensitive drum 48 is rotatably supported by the drum support member 42 so as to be rotatable about a rotation axis of the rotation shaft 41. The charging roller 47 is arranged so as to contact an outer peripheral surface of the photosensitive drum 48, and charges the photosensitive drum 48 by voltage application from the apparatus main body 101. Further, the charging roller 47 rotates following the photosensitive drum 48. A tip of the cleaning blade 43 elastically contacts the photosensitive drum 48, and removes transfer residual toner (hereinafter, waste toner) remaining on the photosensitive drum 48 after the sheet S passes between the photosensitive drum 48 and the transfer roller 125. The removed waste toner is accommodated in the waste toner accommodating portion 44.

The developing unit 50 has a developing chamber 51 in which the developing roller 46, a supply roller 54, and a developing blade 55 are arranged, and a toner accommodating portion 60 that supplies toner to the developing chamber 51. The developing roller 46 supplies toner to a developing region of the photosensitive drum 48, and develops an electrostatic latent image formed on the photosensitive drum 48 using toner (developer). The developing blade 55 abuts against the developing roller 46 to regulate an amount of toner adhering to a peripheral surface of the developing roller 46, and at the same time imparts triboelectric charge to the toner. The supply roller 54 rubs against the developing roller 46 to supply toner in the developing chamber 51 to the developing roller 46, while scraping off excess toner adhering to the developing roller 46.

Toner contained in the toner accommodating portion 60 is sent out to the developing chamber 51 by rotation of a stirring member 63 and is supplied to the developing roller 46. The stirring member 63 is composed of a stirring shaft 63a and a stirring sheet 63b, and is rotatably supported by a developing frame body 52 so as to be rotatable around a rotation axis of the stirring shaft 63a. One end of the stirring sheet 63b is fixed to the stirring shaft 63a, and another end side is a free end that bends following an inner wall of the toner accommodating portion 60 and periodically circulates and stirs the toner. Further, in the toner accommodating portion 60, a first electrode 61 as a first electrode portion and a second electrode 62 as a second electrode portion that constitute electrostatic capacitance are provided substantially parallel so as to face each other with a space therebetween inside of the toner accommodating portion 60. That is, a first electrode 61 and a second electrode 62 used for detecting electrostatic capacitance inside of the toner accommodating portion 60 are provided in a frame body of the developing unit 50 constituting the toner accommodating portion 60 so as to be exposed to the toner accommodating portion 60, respectively. In the rotation direction of the stirring member 63, the first electrode 61 is positioned upstream, and the second electrode 62 is positioned downstream. A detection capacitor C is formed by the first electrode 61 and the second electrode 62, and is arranged substantially parallel to the longitudinal direction Z1, Z2. By the rotation of the stirring member 63, toner enters and exits between the first electrode 61 and the second electrode 62. Due to this entry and exit of toner, the electrostatic capacitance between the first electrode 61 and the second electrode 62 changes according to the rotation cycle of the stirring member 63.

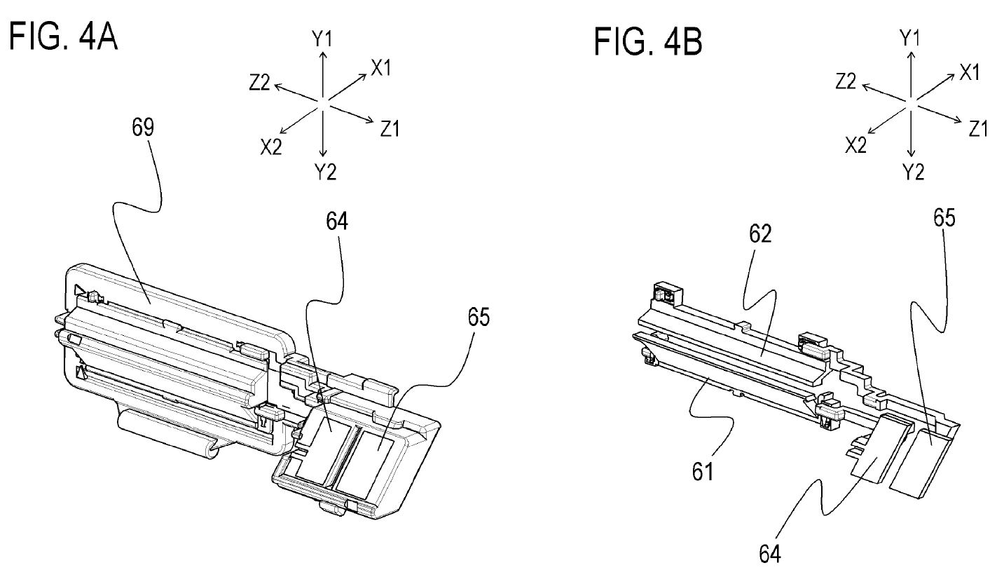

FIG. 4A is a perspective view of an electrode holder 69 that holds the first electrode 61 and the second electrode 62. FIG. 4B is a perspective view in which the electrode holder 69 is removed from the state shown in FIG. 4A. As shown in FIG. 4A, a first electrical contact 64 as a first electrical contact portion and a second electrical contact 65 as a second electrical contact portion for contacting springs on the apparatus main body side (not shown), which will be described later, are exposed from the electrode holder 69. An exposed surface (first contact surface) of the first electrical contact 64 and an exposed surface (second contact surface) of the second electrical contact 65 each have a surface having a normal line perpendicular to a rotation axis of the photosensitive drum 48. As shown in FIG. 4B, the first electrode 61 and the first electrical contact 64 inside of the developing unit 50 are electrically connected by being integrally molded with conductive resin. Similarly, the second electrode 62 and the second electrical contact 65 inside of the developing unit 50 are electrically connected by being integrally molded with conductive resin. More specifically, a frame body of the developing unit 50 is composed of an insulating part having insulation properties and a conductive part having conductivity. The latter conductive part is integrally molded with the former insulating part so as to be exposed to each of an inside (toner accommodating portion 60) and an outside of the frame body. The conductive part includes a first conductive portion in which a part exposed to the toner accommodating portion 60 serves as the first electrode 61 and a part exposed to an outside of the frame body serves as the first electrical contact 64, and a second conductive portion in which a part exposed to the toner accommodating portion 60 serves as the second electrode 62 and a part exposed to the outside of the frame body serves as the second electrical contact 65. Further, the insulating part is divided into a part (first insulating portion) that rotatably supports the stirring member 63 and the like, and a part (second insulating portion) that is configured separately from the part and in which the conductive part is integrally molded, the former being the developing frame body 52 and the latter part being the electrode holder 69. The first electrode 61 and the second electrode 62 are arranged side by side around a rotation axis of the stirring member 63 above the photosensitive drum 48. The first electrode 61 and the second electrode 62 are located closer to a center of the photosensitive drum 48 in the rotation axis direction than the first electrical contact 64 and the second electrical contact 65 in a rotation axis direction of the photosensitive drum 48 (FIG. 3 and FIGS. 4A and 4B).

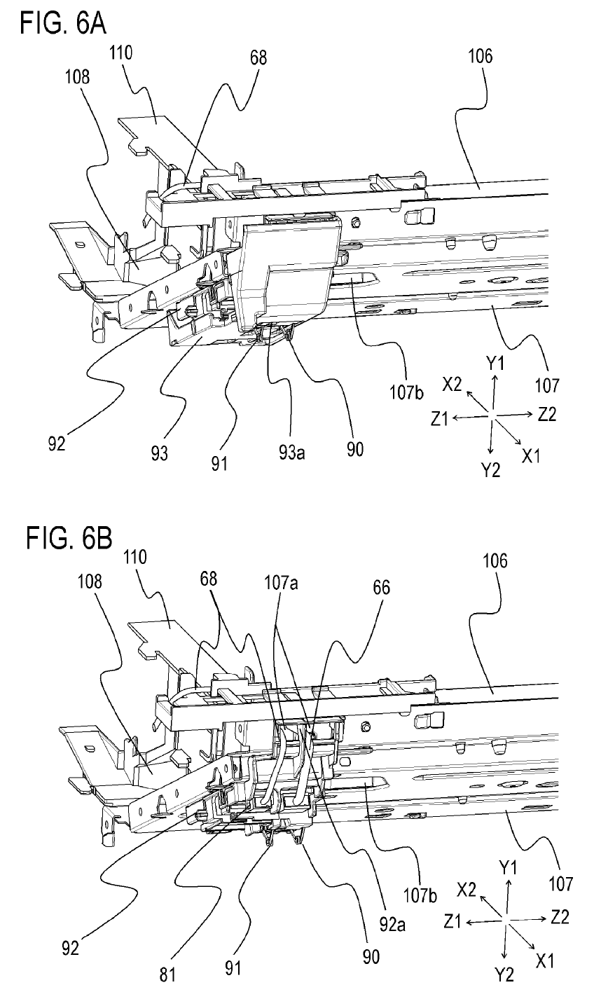

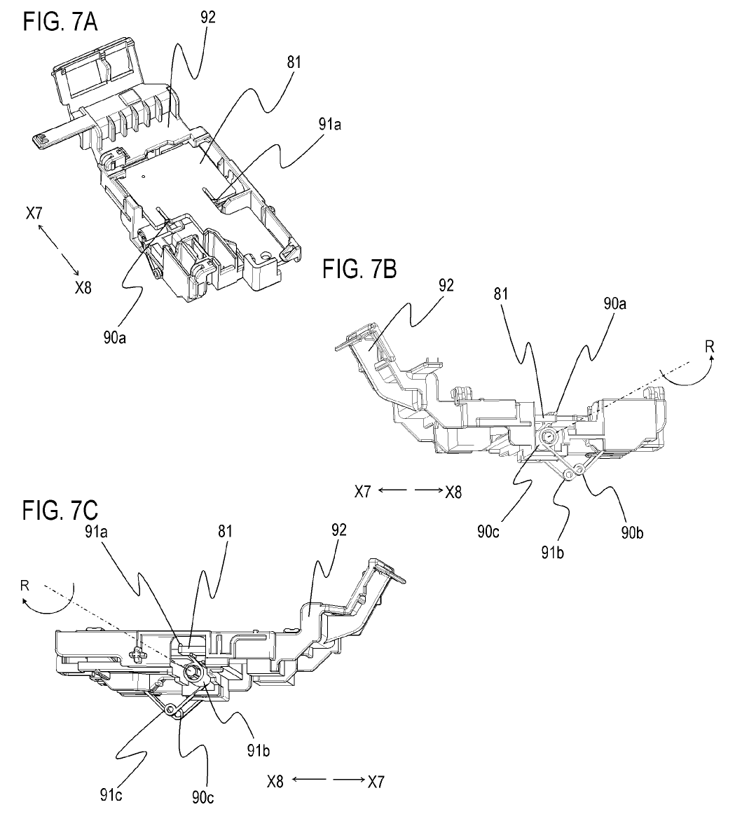

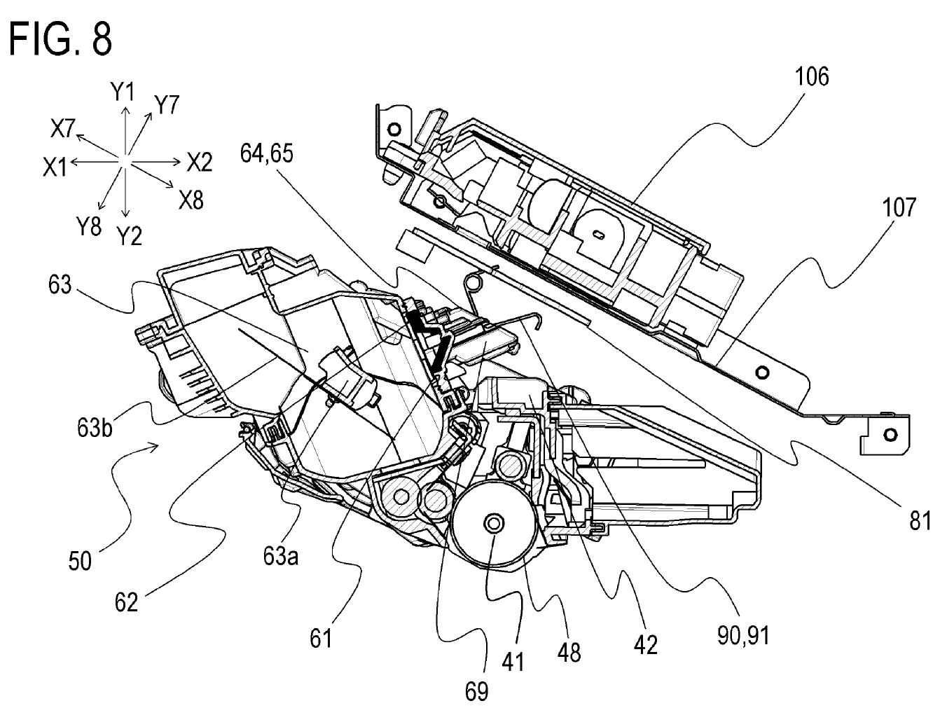

Next, a configuration of the apparatus main body 101 in the present embodiment will be described in detail using FIGS. 5A to 8. FIGS. 5A and 5B are perspective views showing a positional relationship between the process cartridge 15 and the laser scanner 106, FIG. 5A being a view seen from rear upper side, and FIG. 5B being a view seen from the front upper side. FIG. 6A is a perspective view of a frame member 107 viewed from below, and FIG. 6B is a view in which a cover member 93 is removed from FIG. 6A. FIGS. 7A to 7C are perspective views of a second substrate 81, a substrate holder 92, a first spring 90, and a second spring 91. FIG. 8 is a cross-sectional view showing a relationship among the laser scanner 106, the second substrate 81 (current detection portion), the first electrode 61 and the second electrode 62, and the first electrical contact 64 and the second electrical contact 65.

As shown in FIGS. 5A and 5B, the laser scanner 106 arranged above the process cartridge 15 in a gravity direction is fixed to a metallic frame member 107 arranged between the laser scanner 106 and the process cartridge 15. The frame member 107 is provided so as to support the laser scanner 106 below the laser scanner 106. By fixing to the metallic frame member 107, the process cartridge 15 and the laser scanner 106 can be arranged with high rigidity and high accuracy. A first substrate 71 (alternating current voltage source) including an AC voltage output circuit as a power source for applying an alternating current voltage between the first electrical contact 64 and the second electrical contact 65 is fixed above the frame member 107. Further, a second substrate 81 (see FIG. 6B) on which a current detection circuit as a current detection unit for detecting a current flowing between the first electrode 61 and the second electrode 62 is mounted is arranged below the frame member 107, and the second substrate 81 is held by a substrate holder 92. The second substrate 81 is provided such that a normal line direction thereof is a direction perpendicular to a rotation axis of the photosensitive drum 48. The first substrate 71 and the second substrate 81 are electrically connected by a first cable (AC voltage line) 66. A duct 108 for cooling the photosensitive drum 48 is provided on the frame member 107. The first cable 66 is routed along the duct 108, and as shown in FIG. 6B, passes through a hole 107a provided in the frame member 107 and is connected to the second substrate 81. The second substrate 81 and an engine controller (not shown) are connected by a second cable (signal line) 68, and the second cable 68 is routed through the hole 107a of the frame member similarly to the first cable 66.

As shown in FIGS. 7A to 7C, the substrate holder 92 also holds a first spring 90 and a second spring 91 (electrical contact springs). The first and second springs 90, 91 are torsion springs, and contact portions 90a, 91a on the fixed end sides contact the second substrate 81. Contact portions 90b, 91b on free end sides of the first and second springs 90, 91 contact the first electrical contact 64 and the second electrical contact 65 provided on the developing unit 50 with a predetermined pressure. As shown in FIG. 7C, coil portions 90c, 91c of the torsion springs are arranged upstream of the contact portions 90b, 91b with the first electrical contact 64 and the second electrical contact 65 on the free end side with respect to an insertion direction X8 of the process cartridge 15. As a result, the first and second springs 90, 91 rotate in a torsion spring rotation direction R shown in FIGS. 7B and 7C in response to insertion of the process cartridge 15. As shown in FIG. 6A, the substrate holder 92, the first spring 90, and the second spring 91 are covered by a cover member 93, and the contact portions 90b, 91b on the free end sides of the first spring 90 and the second spring 91 are configured to be exposed through a hole 93a provided in the cover member 93. The contact portions 90b, 91b have a shape wound in a one-turn coil shape.

Further, as shown in FIGS. 6A and 6B, the frame member 107 is provided with an outlet 107b for cooling air that has passed through the duct 108. The second substrate 81 is arranged at a position farther from the outlet 107b than the laser scanner 106 in an axial direction of the rotation shaft 41 of the photosensitive drum 48 (the stirring shaft of the stirring member 63). This arrangement enables arrangement without obstructing cooling of the photosensitive drum 48.

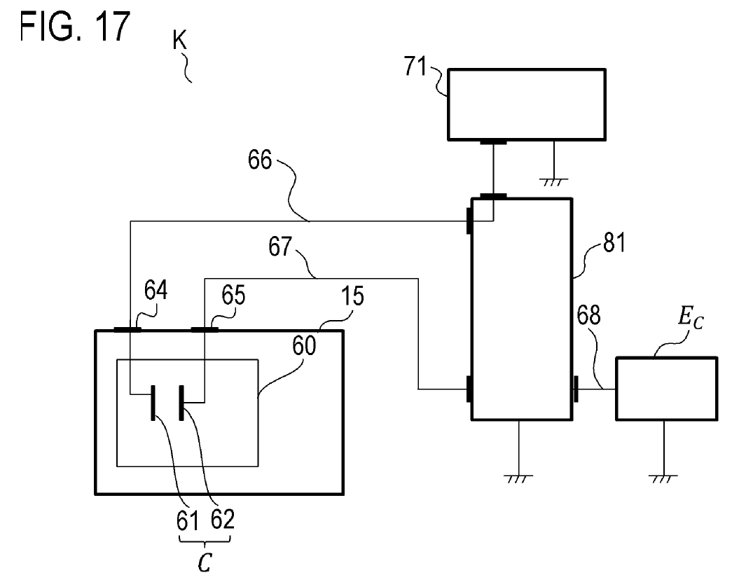

With reference to FIG. 17, a configuration of a toner remaining amount detection circuit K (hereinafter referred to as a remaining amount detection circuit K) in an embodiment of the present disclosure will be described. FIG. 17 is a block diagram showing a wiring configuration among the first substrate 71, the second substrate 81, and the process cartridge 15 in the remaining amount detection circuit K. As shown in FIG. 17, the remaining amount detection circuit K is composed of the first substrate 71 (AC voltage output circuit), the process cartridge 15, and the second substrate 81 (current detection circuit). In the toner accommodating portion 60 of the process cartridge 15, a detection capacitor C that constitutes electrostatic capacitance is formed by the first electrode 61 and the second electrode 62. The first substrate 71 is electrically connected to the first electrode 61, which is one end side of the detection capacitor C provided in the process cartridge 15, via the cable (AC voltage line) 66 and the first electrical contact 64. The second electrode 62, which is another end side of the detection capacitor C, is electrically connected to the second substrate 81 via the second electrical contact 65 and a remaining amount detection signal line 67. The second substrate 81 is electrically connected to an engine controller EC via a cable (signal line) 68.

With these configurations, the AC voltage generated by the AC voltage output circuit on the first substrate 71 is applied to the first electrode 61 through an AC voltage line composed of the first cable 66, the second substrate 81, the first spring 90, and the first electrical contact 64. As a result, a current I corresponding to the electrostatic capacitance between the first electrode 61 and the second electrode 62 flows. This current I flows to the second substrate 81 through a signal line composed of the second electrical contact 65 and the second spring 91, and a current value is detected by the current detection circuit. At this time, since the electrostatic capacitance between the first electrode 61 and the second electrode 62 is minute, the current I is also minute. Since the current I is minute, there is a concern that the current I flowing to the current detection circuit on the second substrate 81 will be greatly affected by stray capacitance with the frame ground in the process.

In contrast, in the present embodiment, as shown in FIG. 8, the second substrate 81 is arranged closer to the first electrical contact 64 or the second electrical contact 65 than the frame member 107 that fixes the laser scanner 106 in a direction perpendicular to the rotation shaft 41 of the photosensitive drum 48. This arrangement can reduce the influence that the current I receives from stray capacitance of the frame ground. As a result, space for securing a distance between the signal line and the frame ground as in the conventional configuration becomes unnecessary, and it becomes possible to accurately detect the remaining amount of toner using an electrostatic capacitance method without increasing the product size.

The arrangement that reduces the influence from stray capacitance can also be specified, for example, as follows. That is, the second substrate 81 is provided between one end (first end) and another end (second end) of the photosensitive drum 48 in the direction of the rotation axis. The first electrical contact 64 and the second electrical contact 65 are arranged between one end (first end) and another end (second end) of the photosensitive drum 48 in the direction of the rotation axis (FIG. 3). The second substrate 81 is arranged at substantially the same position in the direction of the rotation axis with respect to the contact portions 90b, 91b that contact them (FIGS. 6A and 6B and FIGS. 7A and 7B). Furthermore, the second substrate 81 is provided between the laser scanner 106 and the developing unit 50 when viewed in the direction of the rotation axis of the photosensitive drum 48, and is also positioned between the two in a cross section perpendicular to the rotation axis (FIG. 8). Further, the second substrate 81 is at a position that overlaps the photosensitive drum 48 or the drum support member 42 when viewed in directions Y7, Y8 perpendicular to the rotation shaft 41 of the photosensitive drum 48 (FIGS. 5A and 5B and FIG. 8). Further, the second substrate 81 is positioned between the laser scanner 106 and the first electrical contact 64 and the second electrical contact 65 when viewed in the direction of the rotation axis of the photosensitive drum 48 (FIG. 8). More specifically, the second substrate 81 is at a position closer to the first electrical contact 64 or the second electrical contact 65 than the frame member 107 in directions Y7, Y8 perpendicular to the rotation shaft 41 of the photosensitive drum 48 (FIGS. 5A and 5B and FIG. 8). Further, the second substrate 81 is positioned between the frame member 107 and the developing unit 50 when viewed in the direction of the rotation axis of the photosensitive drum 48 (FIG. 8). More specifically, the second substrate 81 is positioned between the frame member 107 and the process cartridge 15 (developing unit 50) in directions Y7, Y8 perpendicular to the rotation shaft 41 of the photosensitive drum 48 (FIGS. 5A and 5B and FIG. 8). Further, the second substrate 81 is at a position closer to the first electrical contact 64 or the second electrical contact 65 than the frame member 107 in directions Y7, Y8 intersecting an attachment/detachment direction X7, X8 of the process cartridge 15 (developing unit 50) (FIG. 8). Further, the second substrate 81 is positioned between the frame member 107 and the developing unit 50 in directions Y7, Y8 intersecting the attachment/detachment direction X7, X8 of the process cartridge 15 (developing unit 50) (FIG. 8). Further, the second substrate 81 is at a position closer to the first electrical contact 64 or the second electrical contact 65 than the frame member 107 in a normal line direction thereof, that is, in directions Y7, Y8 perpendicular to the second substrate 81 (FIG. 8). Further, the second substrate 81 is positioned between the frame member 107 and the process cartridge 15 (developing unit 50) in directions Y7, Y8 perpendicular to the second substrate 81 (FIG. 8). Further, the second substrate 81 is provided at a position farther from a center of the photosensitive drum 48 in the direction of the rotation axis than the laser scanner 106 in the direction of the rotation axis of the photosensitive drum 48 (FIGS. 5A and 5B and FIGS. 6A and 6B). Further, the second substrate 81 is at a position that does not overlap the laser scanner 106 when viewed in directions Y7, Y8 perpendicular to the rotation shaft 41 of the photosensitive drum 48 (FIGS. 5A and 5B and FIGS. 6A and 6B). Further, it is at a position closer to the first electrical contact 64 or the second electrical contact 65 than the frame member 107 in directions Y7, Y8 perpendicular to the rotation axis of the stirring member 63 (FIG. 8). Further, the second substrate 81 is at a position that overlaps the frame member 107 when viewed in directions Y7, Y8 perpendicular to the rotation axis of the stirring member 63 (FIG. 8). Further, the second substrate 81 is at a position that overlaps the process cartridge 15 (developing unit 50) when viewed in directions Y7, Y8 perpendicular to the rotation axis of the stirring member 63 (FIG. 8). The second substrate 81 is positioned between the frame member 107 and the developing unit 50 in directions Y7, Y8 perpendicular to the rotation axis of the stirring member 63 (FIG. 8).

In the present embodiment, the AC voltage output circuit and the current detection circuit are mounted on different substrates, but may be mounted on the same substrate. Further, the AC voltage line may not pass through the second substrate 81.

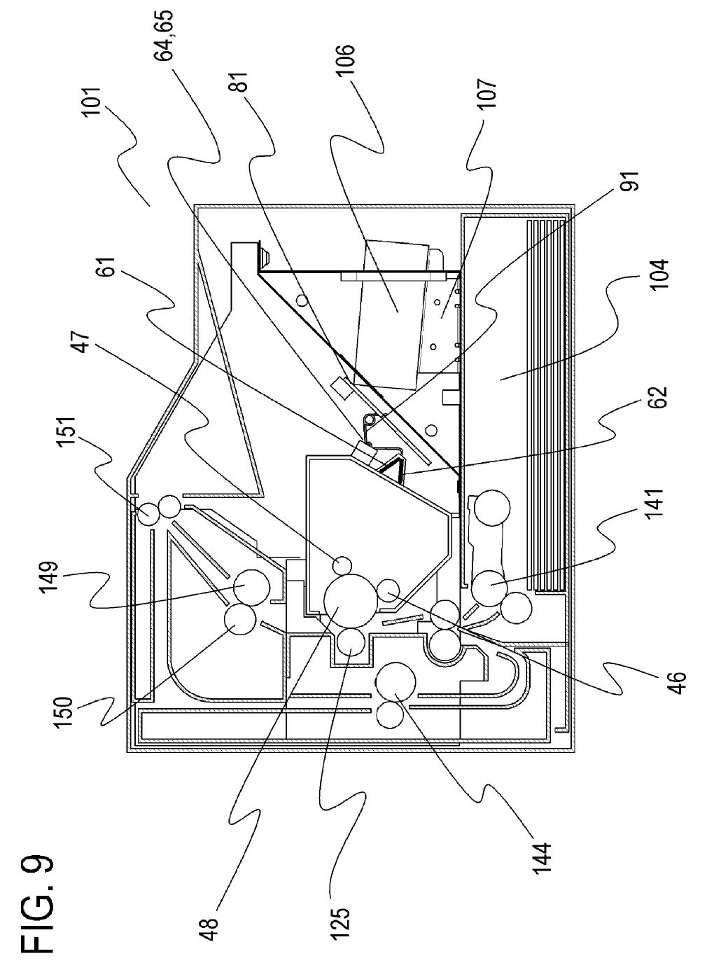

In the present embodiment, an image forming apparatus including an S-path in which a sheet conveyance path has an S-shape when viewed from a side has been described, but the present disclosure may be applied to an image forming apparatus including a C-path in which a sheet conveyance path has a C-shape as shown in FIG. 9. FIG. 9 is a schematic cross-sectional view of an image forming apparatus according to a modification of the present embodiment, and is a cross-sectional view showing a relationship among the laser scanner 106, the second substrate 81 (current detection portion), and the first electrical contact 64 and the second electrical contact 65. In the modification, portions having the same functions as in the present embodiment are denoted by the same reference numerals. In FIG. 9, an optical path of laser light of the laser scanner 106 is not illustrated.

Even in an apparatus in which the sheet conveyance path is a C-path, as shown in FIG. 9, the second substrate 81 may be arranged closer to the first electrical contact 64 and the second electrical contact 65 than the frame member 107 that fixes the laser scanner 106. As a result, the influence that the current I receives from stray capacitance of the frame ground can be reduced.

### Embodiment 2

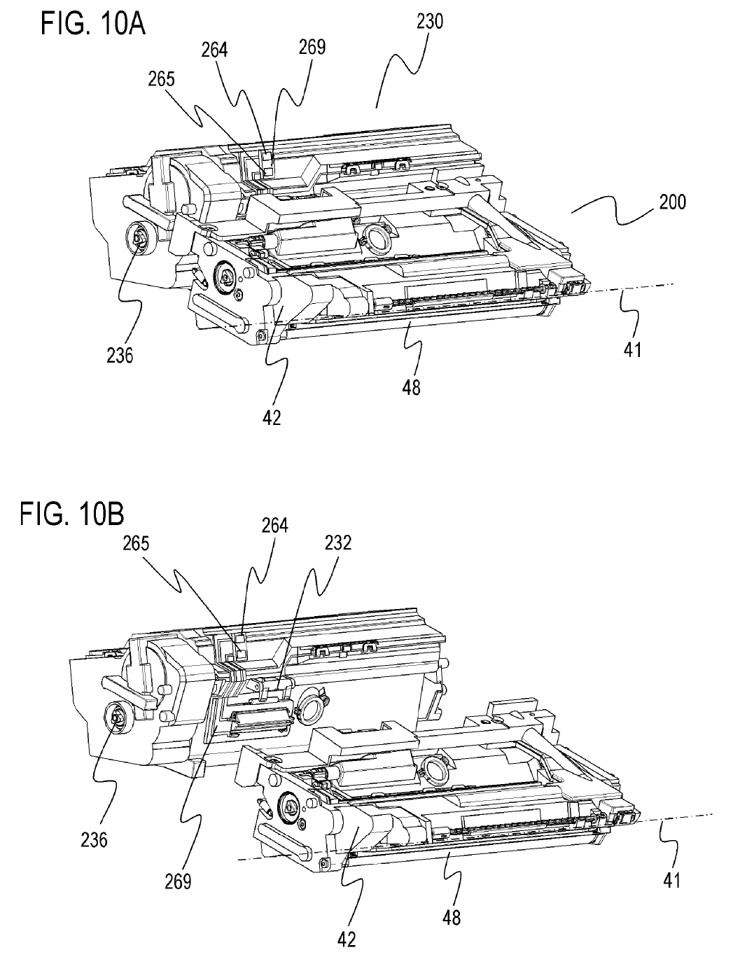

With reference to FIGS. 10A to 16, an image forming apparatus according to Embodiment 2 of the present disclosure will be described. In Embodiment 2, the same or corresponding portions as in Embodiment 1 are denoted by the same reference numerals, and detailed description thereof is omitted. The present embodiment is an example in which the present disclosure is applied to a toner detection portion of a toner cartridge (developer accommodating unit) that supplies toner to a process cartridge.

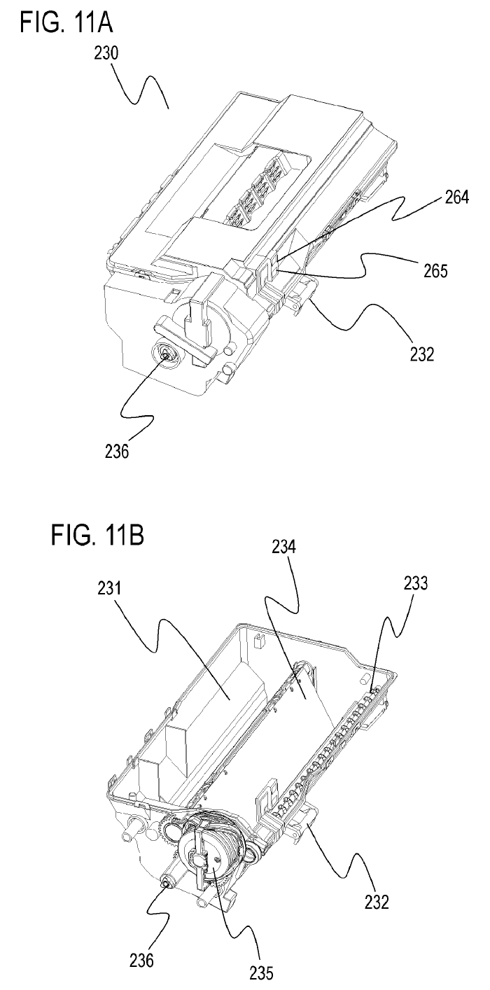

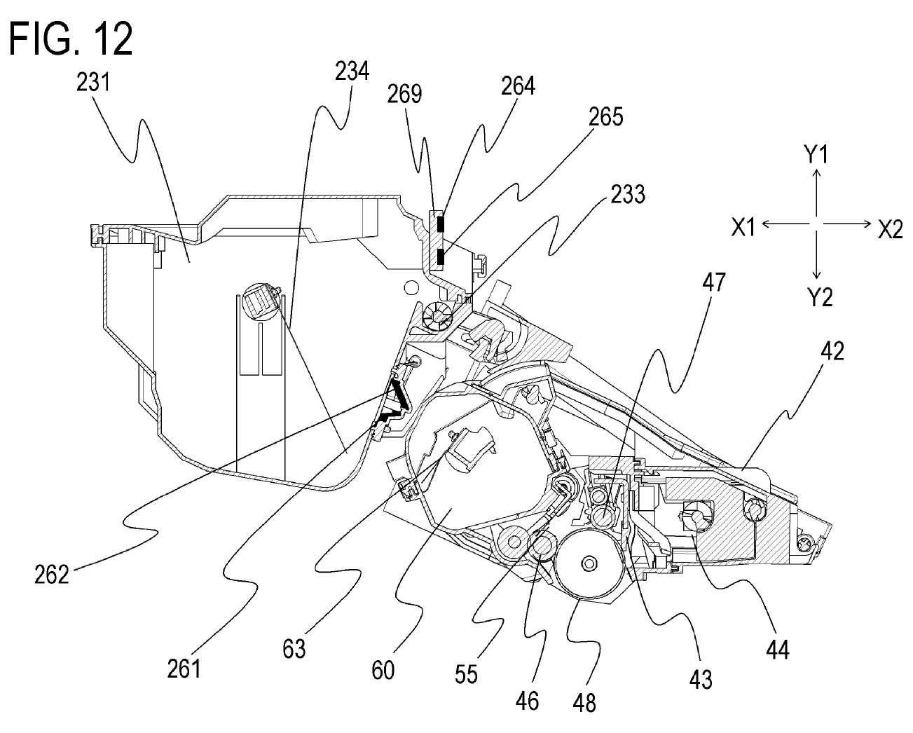

FIGS. 10A and 10B are perspective views of a process cartridge 200 and a toner cartridge 230. FIG. 10A shows a state in which the process cartridge 200 and the toner cartridge 230 are integrated, and FIG. 10B shows a state in which the process cartridge 200 and the toner cartridge 230 are separated. FIG. 11A is a perspective view of the toner cartridge 230, and FIG. 11B is a perspective view of the toner cartridge 230 with a cover member 293 removed. FIG. 12 is a cross-sectional view of the process cartridge 200 and the toner cartridge 230.

The toner cartridge 230 is configured to be attachable to and detachable from the apparatus main body 101 in a state where the process cartridge 200 including the photosensitive drum 48 and the developing roller 46 is mounted to the apparatus main body 101. The toner cartridge 230 has a toner accommodating portion 231 that accommodates toner and a toner discharge port 232 that discharges toner to the process cartridge 200. Further, the toner cartridge 230 has a screw member 233 that conveys toner toward the toner discharge port 232, a toner stirring member 234 that stirs and conveys toner toward the screw member, and a pump portion 235. Furthermore, the toner cartridge 230 has a drive input portion 236 that inputs a driving force from the apparatus main body 101 to the toner cartridge 230. The toner stirring member 234 is composed of a stirring shaft 234a and a stirring sheet 234b, and is rotatably supported by a frame body of the toner cartridge 230 so as to be rotatable around a rotation axis of the stirring shaft 234a. One end of the stirring sheet 234b is fixed to the stirring shaft 234a, and another end side is a free end that bends following an inner wall of the toner accommodating portion 231 and periodically circulates and stirs the toner. The screw member 233 and the toner stirring member 234 rotate by rotational driving force transmitted from the drive input portion 236 and convey toner in the toner accommodating portion 231 to the toner discharge port 232. The pump portion 235 receives rotational driving and expands and contracts, whereby a volume fluctuates, discharging toner from the toner discharge port 232 to the process cartridge 200.

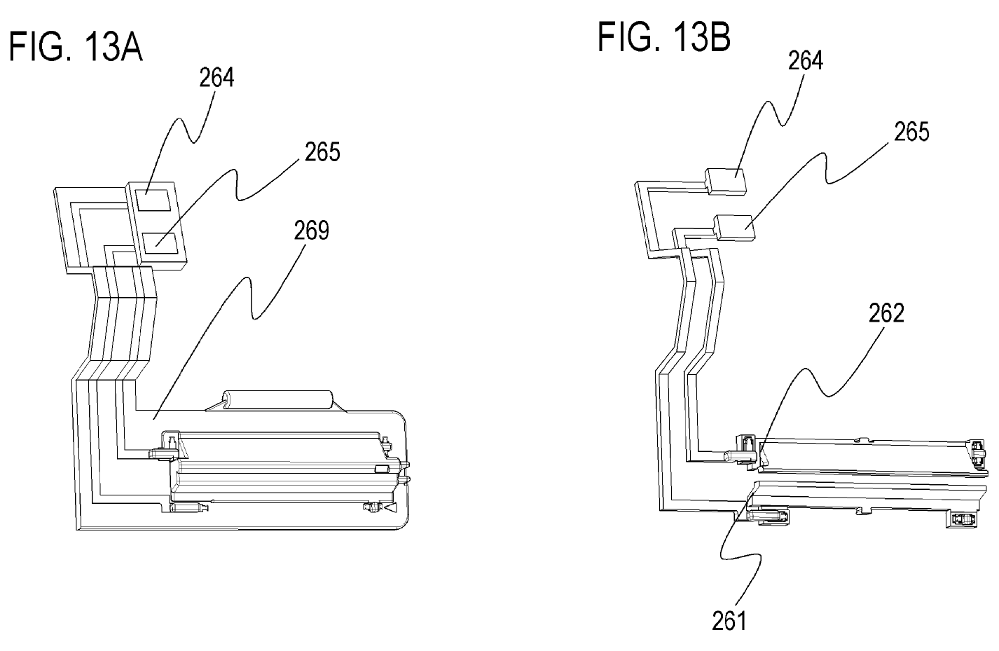

FIGS. 13A and 13B are perspective views of an electrode holder 269 that holds a first electrode 261 and a second electrode 262. As shown in FIG. 13A, a first electrical contact 264 and a second electrical contact 265 for contacting springs on the apparatus main body 101 side, which will be described later, are exposed from the electrode holder 269. FIG. 13B is a perspective view in which the electrode holder 269 is removed from the state shown in FIG. 13A. The first electrode 261 and the first electrical contact 264 inside of the toner cartridge 230, and the second electrode 262 and the second electrical contact 265 are electrically connected by being integrally molded with conductive resin.

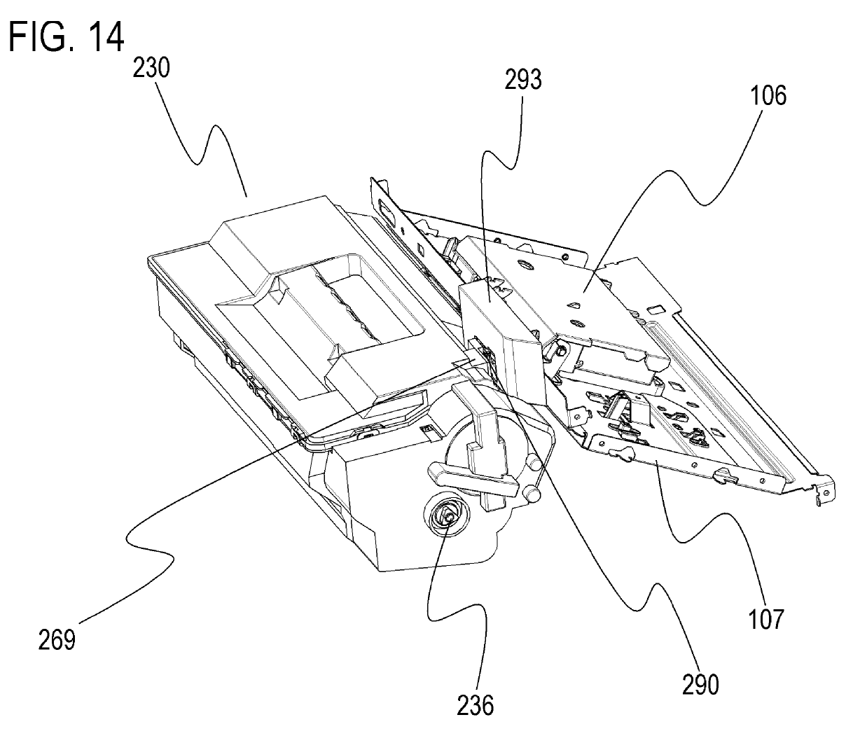

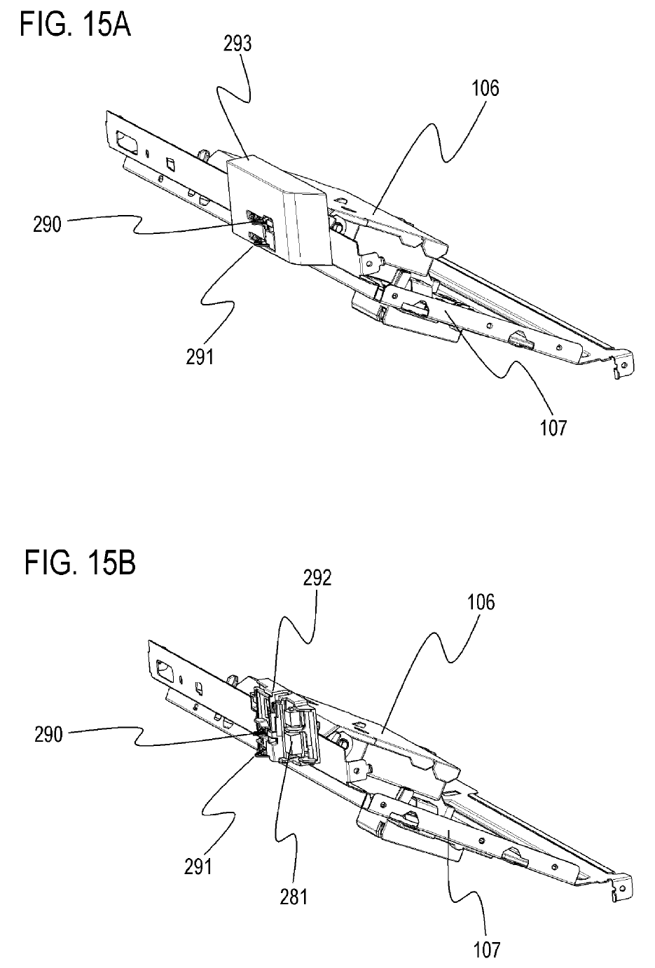

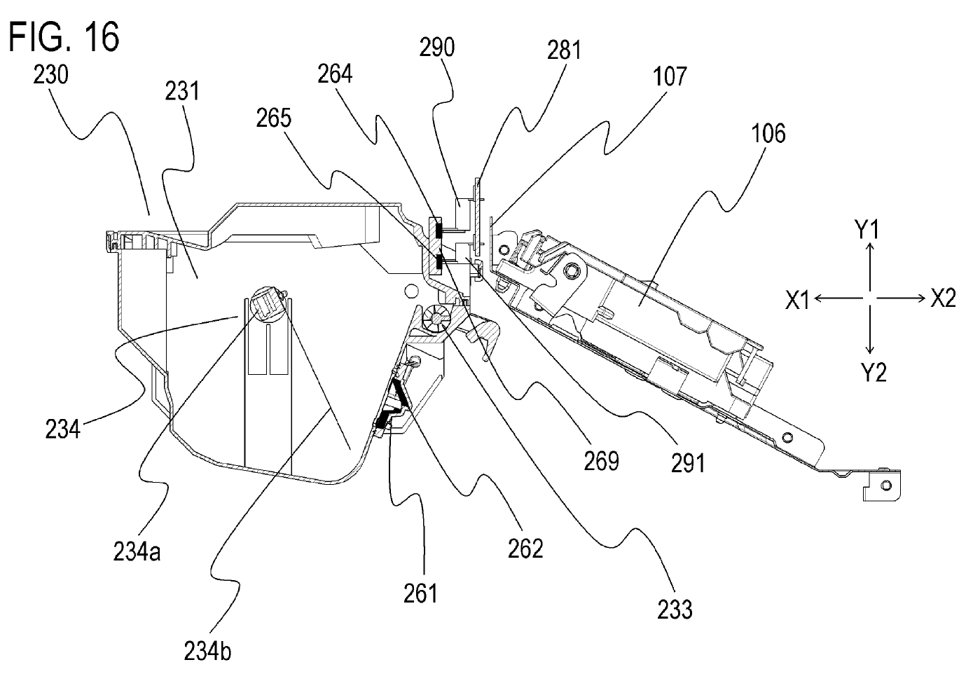

Next, a configuration of the apparatus main body 101 in the present embodiment will be described in detail using FIGS. 14 to 16. FIG. 14 is a perspective view showing a positional relationship between the toner cartridge 230 and the laser scanner 106. FIG. 15A is a perspective view of the frame member 107 viewed from above, and FIG. 15B is a view in which a cover member 293 is removed from FIG. 15A. FIG. 16 is a cross-sectional view showing a relationship among the laser scanner 106, a second substrate 281 (current detection portion), and the first electrical contact 264 and the second electrical contact 265.

As shown in FIG. 14, the laser scanner 106 arranged in a horizontal direction of the toner cartridge 230 is fixed to a metallic frame member 107 arranged between the laser scanner 106 and the toner cartridge 230. As shown in FIGS. 15A and 15B, a second substrate 281 (current detection portion) including a current detection circuit is held between the toner cartridge 230 and the frame member 107 by a substrate holder 292. Further, the substrate holder 292 also holds a first spring 290 and a second spring 291. The first spring 290 and the second spring 291 are torsion springs, and contact the first electrical contact 264 and the second electrical contact 265 provided on the toner cartridge 230 with a predetermined pressure. As shown in FIG. 15B, the substrate holder 292, the first spring 290, and the second spring 291 are covered by a cover member 293.

With these configurations, the AC voltage is applied to the first electrode 261 via the second substrate 281, the first spring 290, and the first electrical contact 264, and a current I corresponding to the electrostatic capacitance between the first electrode 261 and the second electrode 262 flows. This current I flows to the second substrate 281 through a signal line composed of the second electrical contact 265 and the second spring 291, and a current value is detected by the current detection circuit. Since the electrostatic capacitance between the first electrode 261 and the second electrode 262 is minute, the current I is also minute. Since the current I is minute, there is a concern that the current I flowing to the current detection circuit on the second substrate 281 will be greatly affected by stray capacitance with the frame ground in the process.

In contrast, in the present embodiment, as shown in FIG. 16, the second substrate 281 is arranged closer to the first electrical contact 264 or the second electrical contact 265 than the frame member 107 that fixes the laser scanner 106 in a direction perpendicular to the rotation shaft 41 of the photosensitive drum 48. This arrangement can reduce the influence that the current I receives from stray capacitance of the frame ground. As a result, space for securing a distance between the signal line and the frame ground as in the conventional configuration becomes unnecessary, and it becomes possible to accurately detect the remaining amount of toner using an electrostatic capacitance method without increasing the product size.

The arrangement that reduces the influence from stray capacitance can also be specified, for example, as follows. That is, the second substrate 281 is provided between one end (first end) and another end (second end) of the photosensitive drum 48 in the direction of the rotation axis (FIG. 14 and FIGS. 15A and 15B). Furthermore, the second substrate 281 is provided between the laser scanner 106 and the toner cartridge 230 when viewed in the direction of the rotation axis of the photosensitive drum 48, and is also positioned between the two in a cross section perpendicular to the rotation axis (FIG. 16). Further, the second substrate 281 is at a position that overlaps the photosensitive drum 48 or the drum support member 42 when viewed in a direction perpendicular to the rotation shaft 41 of the photosensitive drum 48 (FIGS. 12 and 16). Further, the second substrate 281 is positioned between the laser scanner 106 and the first electrical contact 264 and the second electrical contact 265 when viewed in the direction of the rotation axis of the photosensitive drum 48 (FIG. 16). More specifically, the second substrate 281 is at a position closer to the first electrical contact 264 or the second electrical contact 265 than the frame member 107 in directions X1, X2 perpendicular to the rotation shaft 41 of the photosensitive drum 48 (FIGS. 12 and 16). Further, the second substrate 281 is positioned between the frame member 107 and the toner cartridge 230 when viewed in the direction of the rotation axis of the photosensitive drum 48 (FIG. 16). More specifically, the second substrate 281 is positioned between the frame member 107 and the toner cartridge 230 in directions X1, X2 perpendicular to the rotation shaft 41 of the photosensitive drum 48 (FIG. 16). Further, the second substrate 281 is at a position closer to the first electrical contact 264 or the second electrical contact 265 than the frame member 107 in a normal line direction thereof, that is, in directions X1, X2 perpendicular to the second substrate 281 (FIG. 16). Further, the second substrate 281 is positioned between the frame member 107 and the toner cartridge 230 in directions X1, X2 perpendicular to the second substrate 281 (FIG. 16). Further, the second substrate 281 is provided at a position farther from a center of the photosensitive drum 48 in the direction of the rotation axis than the laser scanner 106 in the direction of the rotation axis of the photosensitive drum 48 (FIG. 14 and FIGS. 15A and 15B). Further, the second substrate 281 is at a position that does not overlap the laser scanner 106 when viewed in a direction perpendicular to the rotation shaft 41 of the photosensitive drum 48 (FIGS. 15A and 15B and FIG. 16). Further, it is at a position closer to the first electrical contact 264 or the second electrical contact 265 than the frame member 107 in directions X1, X2 perpendicular to the rotation axis of the toner stirring member 234 (FIG. 16). Further, the second substrate 281 is at a position that overlaps the frame member 107 when viewed in directions X1, X2 perpendicular to the rotation axis of the toner stirring member 234 (FIG. 16). Further, the second substrate 281 is at a position that overlaps the toner cartridge 230 when viewed in directions X1, X2 perpendicular to the rotation axis of the toner stirring member 234 (FIG. 16). The second substrate 281 is positioned between the frame member 107 and the toner cartridge 230 in directions X1, X2 perpendicular to the rotation axis of the toner stirring member 234 (FIG. 16).

According to the present disclosure, it is possible to suppress a decrease in detection accuracy of the remaining amount of developer.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-035940, filed on March 6, 2025, which is hereby incorporated by reference herein in its entirety.

What is claimed is:

1. An image forming apparatus, comprising:
a photosensitive drum that rotates about a rotation axis, the photosensitive drum having a first end that is one end in a direction of the rotation axis and a second end that is another end in the direction of the rotation axis;
a developing unit having a developing roller that supplies developer to the photosensitive drum, and an accommodating portion that accommodates developer to be borne on the developing roller; and
an apparatus main body having an exposure unit that exposes the photosensitive drum,
wherein the developing unit has a first electrode portion and a second electrode portion, and a first electrical contact portion and a second electrical contact portion, the first electrode portion and the second electrode portion being provided so as to face each other with a space therebetween inside of the accommodating portion, the first electrical contact portion being electrically connected to the first electrode portion and exposed to an outside of the developing unit, the second electrical contact portion being electrically connected to the second electrode portion and exposed to the outside of the developing unit,
wherein the apparatus main body has a power source and a current detection portion, the power source being configured to apply an alternating current voltage between the first electrical contact portion and the second electrical contact portion, the current detection portion being configured to detect a current flowing between the first electrode portion and the second electrode portion, and
wherein the current detection portion is provided between the first end and the second end of the photosensitive drum in the direction of the rotation axis, and is provided between the exposure unit and the developing unit when viewed in the direction of the rotation axis.

2. The image forming apparatus according to claim 1, wherein
the current detection portion is positioned between the exposure unit and the developing unit in a cross section perpendicular to the rotation axis.

3. The image forming apparatus according to claim 1, wherein
the current detection portion is provided at a position farther from a center of the photosensitive drum in the direction of the rotation axis than the exposure unit in the direction of the rotation axis of the photosensitive drum.

4. The image forming apparatus according to claim 1, wherein
the apparatus main body has a frame member positioned below the exposure unit to support the exposure unit, and
the current detection portion is provided between the frame member and the developing unit when viewed in the direction of the rotation axis.

5. The image forming apparatus according to claim 1, wherein
the developing unit and the photosensitive drum are configured to be attachable to and detachable from the apparatus main body as an integrated cartridge.

6. The image forming apparatus according to claim 1, wherein
the current detection portion includes a substrate on which a current detection circuit is mounted, and
the substrate is provided such that a normal line to the substrate is perpendicular to the rotation axis.

7. The image forming apparatus according to claim 1, wherein
the first electrical contact portion includes a first contact surface having a normal line perpendicular to the rotation axis, and the second electrical contact portion includes a second contact surface having a normal line perpendicular to the rotation axis, and
the current detection portion is provided between the exposure unit and the first electrical contact portion and the second electrical portion contact when viewed in the direction of the rotation axis.

8. The image forming apparatus according to claim 1, wherein
in the direction of the rotation axis, the first electrode portion and the second electrode portion are located closer to a center of the photosensitive drum in the direction of the rotation axis than the first electrical contact portion and the second electrical contact portion.

9. An image forming apparatus, comprising:
a photosensitive drum that rotates about a rotation axis, the photosensitive drum having a first end that is one end in a direction of the rotation axis and a second end that is another end in the direction of the rotation axis;
a developing unit having a developing roller that supplies developer to the photosensitive drum;
a developer accommodating unit having an accommodating portion that accommodates developer to be borne on the developing roller; and
an apparatus main body having an exposure unit that exposes the photosensitive drum,
wherein the developer accommodating unit has a first electrode portion and a second electrode portion, and a first electrical contact portion and a second electrical contact portion, the first electrode portion and the second electrode portion being provided so as to face each other with a space therebetween inside of the accommodating portion, the first electrical contact portion being electrically connected to the first electrode portion and exposed to an outside of the developer accommodating unit, the second electrical contact portion being electrically connected to the second electrode portion and exposed to the outside of the developer accommodating unit,
wherein the apparatus main body has a power source and a current detection portion, the power source being configured to apply an alternating current voltage between the first electrical contact portion and the second electrical contact portion, the current detection portion being configured to detect a current flowing between the first electrode portion and the second electrode portion, and
wherein the current detection portion is provided between the first end and the second end of the photosensitive drum in the direction of the rotation axis, and is provided between the exposure unit and the developer accommodating unit when viewed in the direction of the rotation axis.

10. The image forming apparatus according to claim 9, wherein
the developer accommodating unit is configured to be attachable to and detachable from the apparatus main body in a state where the photosensitive drum and the developing roller remaining in the apparatus main body.
